(19) United States
(12) Patent Application Publication
(10) Pub. No.: US 2026/0173556 A1
(43) Pub. Date: Jun. 18, 2026

(54) IMAGE SENSOR

(71) Applicant: SAMSUNG ELECTRONICS CO., LTD., Suwon-si (KR)

(72) Inventors: Seungjae Lee, Suwon-si (KR); Donghyun Kim, Suwon-si (KR); Kyeongmin Nam, Suwon-si (KR); Woobin Bae, Suwon-si (KR); Sehoon Yoo, Suwon-si (KR); Minjun Choi, Suwon-si (KR)

(73) Assignee: SAMSUNG ELECTRONICS CO., LTD., Suwon-si (KR)

(21) Appl. No.: 19/413,603

(22) Filed: Dec. 9, 2025

(30) Foreign Application Priority Data
Dec. 18, 2024 (KR) 10-2024-0189963

(51) Int. Cl. H10F 39/00; H04N 25/703; H04N 25/79; H10F 39/18

(52) U.S. Cl. CPC H10F 39/806; H04N 25/703; H04N 25/79; H10F 39/182; H10F 39/8057; H10F 39/809; H10F 39/811

(57) ABSTRACT

An image sensor includes a stack structure comprising a first substrate having a first surface, and a second surface, and including a photoelectric conversion region for each pixel of ae plurality of pixels; a first interconnection structure including a first interconnection and a first inter-interconnection insulating layer on the second surface; a second substrate including logic elements for driving the plurality of pixels on the first interconnection structure of the first substrate; a second interconnection structure disposed between the second substrate and the first interconnection structure, and including a second interconnection and a second inter-interconnection insulating layer; a inorganic layer including an inorganic material on the first surface; and a meta-optical structure including a plurality of dielectric layers on the inorganic layer, and nano-prism patterns arranged in at least one dielectric layer among the plurality of dielectric layers.

### CROSS-REFERENCE TO RELATED APPLICATION(S)

This application is based on and claims of priority to Korean Patent Application No. 10-2024-0189963 filed on Dec. 18, 2024 in the Korean Intellectual Property Office, the disclosure of which is incorporated herein by reference in its entirety.

### BACKGROUND

The present disclosure relates to an image sensor.

An image sensor may be a semiconductor-based sensor that receives light according to a position and a color corresponding to an image formed by an optical structure, and generates an electrical signal based thereon. As the optical structure of the image sensor, a micro lens and a color filter may mainly be used for each pixel. However, as a demand for a high-resolution camera increases, a size of the optical structure is in a trend of decreasing as a pixel becomes increasingly ultra-fine.

However, due to miniaturization of the optical structure, an optical efficiency of the image sensor may decrease. As an alternative to a related art optical structure, a method of introducing a structure based on a new optical technology called “meta-optics” is being actively studied.

### SUMMARY

An aspect of one or more example embodiments of the present disclosure is to provide an image sensor having improved reliability.

According to an aspect of an example embodiment of the present disclosure, an image sensor includes a substrate comprising an active pixel region, an optical black region, a pad region, a first surface, and a second surface opposing the first surface, a plurality of photoelectric conversion regions in the active pixel region, a first insulating layer on the second surface of the substrate and on the active pixel region, an inorganic layer on the first insulating layer, and a meta-optical structure disposed on the inorganic layer, and comprising a first dielectric layer, first nano-prism patterns arranged in the first dielectric layer, a second dielectric layer, and second nano-prism patterns arranged in the second dielectric layer, wherein the meta-optical structure is disposed on the active pixel region, and wherein a height of the inorganic layer in a first direction perpendicular to the second surface of the substrate on the active pixel region is more than 20 times greater than a height of the insulating layer.

According to an aspect of the present disclosure, an image sensor includes a substrate comprising an active pixel region, an optical black region, a pad region, a first surface, and a second surface opposing the first surface, a plurality of photoelectric conversion regions in the active pixel region, a first insulating layer on the second surface of the substrate and on the active pixel region, an inorganic layer on the first insulating layer, a light-blocking filter layer in the inorganic layer, and a meta-optical structure disposed on the inorganic layer, and comprising a first layer, first nano-prism patterns arranged in the first layer, a second layer, and second nano-prism patterns arranged in the second layer, wherein the meta-optical structure is disposed on the active pixel region and optical black region.

According to an aspect of the present disclosure, an image sensor includes a substrate comprising an active pixel region, an optical black region, a pad region, a first surface, and a second surface opposing the first surface, a plurality of photoelectric conversion regions in the active pixel region, a first insulating layer on the second surface of the substrate and on the active pixel region, an inorganic layer on the first insulating layer, and a meta-optical structure disposed on the inorganic layer, and comprising a first layer, first nano-prism patterns arranged in the first layer, a second layer, and second nano-prism patterns arranged in the second layer, wherein the meta-optical structure is disposed on the active pixel region, and wherein a height of the inorganic layer in a first direction perpendicular to the second surface of the substrate on the active pixel region is greater than a height of the first nano-prism patterns in the first direction on the active pixel region.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is an exploded perspective view illustrating an image sensor according to an embodiment.

FIG. 2 is a plan view of portion “A” of the image sensor of FIG. 1, and FIG. 3 is a cross-sectional side view of FIG. 2, taken along line I-I′.

FIG. 4 is a cross-sectional side view illustrating an image sensor according to an embodiment.

FIGS. 5 and 6 are side sectional views illustrating image sensors according to various embodiments, respectively.

FIG. 7 is a cross-sectional side view illustrating an image sensor according to embodiments.

FIGS. 8 and 9 are cross-sectional side views illustrating image sensors according to various embodiments.

### DETAILED DESCRIPTION

Hereinafter, one or more example embodiments of the present disclosure will be described with reference to the accompanying drawings. One of ordinary skill would understand that aspects of some embodiments may be combined together or implemented alone.

In the specification, the expression that a first component (or area, layer, part, portion, etc.) is “disposed on”, “connected with” or “coupled to” a second component means that the first component is directly disposed on and/or connected with and/or coupled to the second component or means that a third component is interposed therebetween.

The same reference numerals may refer to the same components. Further, in the drawings, the thickness, the ratio, and the dimension of components may be exaggerated for effective description of technical contents. As used herein, an expression “at least one of” preceding a list of elements modifies the entire list of the elements and does not modify the individual elements of the list. For example, an expression, “at least one of a, b, and c” (or “at least one of a, b, or c”) should be understood as including only a, only b, only c, both a and b, both a and c, both b and c, or all of a, b, and c.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

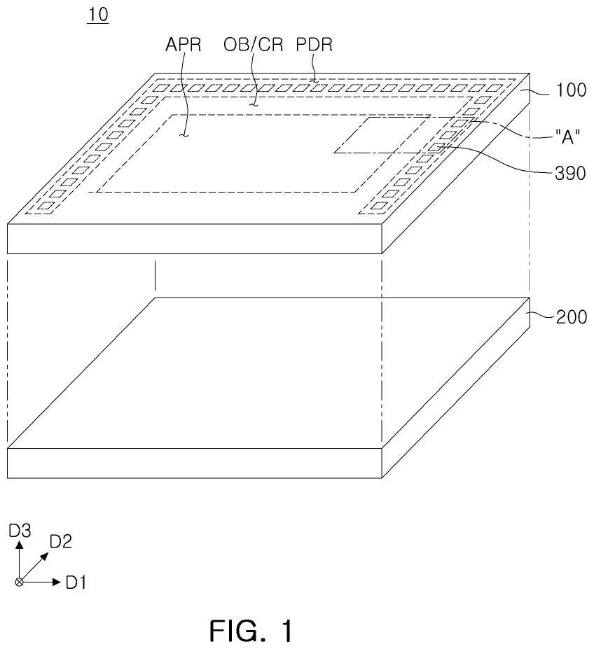

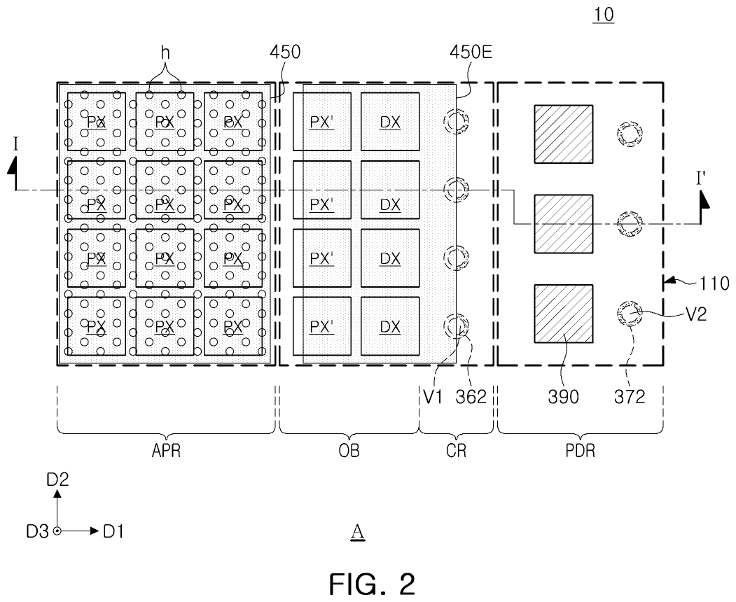

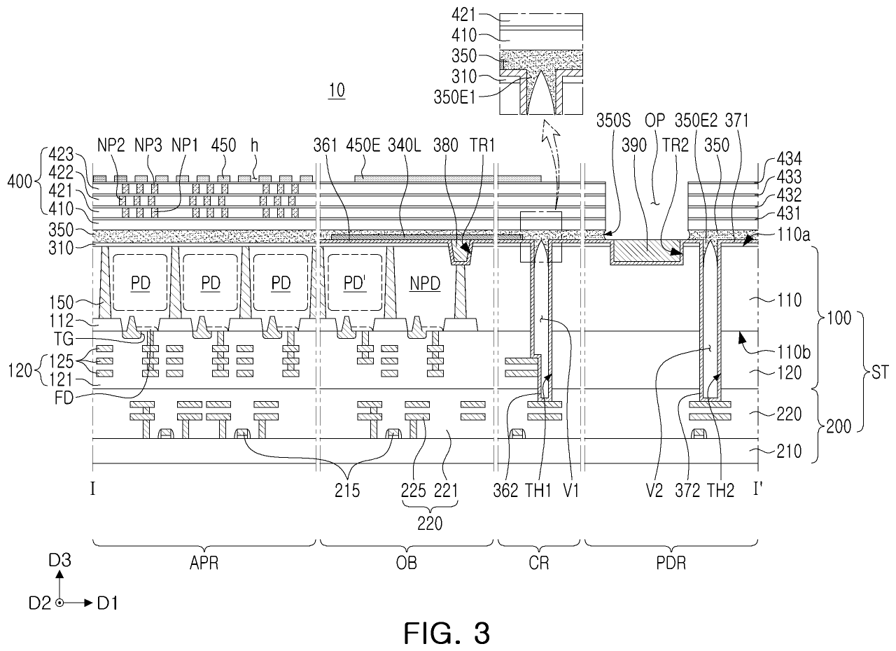

FIG. 1 is an exploded perspective view illustrating an image sensor according to an embodiment, FIG. 2 is a plan view of portion “A” of the image sensor of FIG. 1, and FIG. 3 is a cross-sectional side view of FIG. 2, taken along line I-I′.

Referring to FIGS. 1 to 3, an image sensor 10 according to an embodiment may include a stack structure ST in which a first substrate structure 100 and a second substrate structure 200 are stacked and electrically connected to each other. The stack structure ST employed in the present embodiment may include an active pixel region APR in which a plurality of pixels PX are arranged, a pad region PDR disposed on at least one side of the active pixel region APR, and an optical black region OB and a connection region CR, between the active pixel region APR and the pad region PDR.

As illustrated in FIG. 1, the active pixel region APR may be disposed in an internal region of the stack structure ST. The plurality of pixels PX may be disposed in the active pixel region APR. The plurality of pixels PX may be disposed on a first substrate 110 in a matrix shape in rows and columns in a first direction D1 and a second direction D2, which is perpendicular to the first direction D1, in the active pixel region APR.

Each of the plurality of pixels PX may include at least one photoelectric conversion region PD formed in the first substrate 110. The plurality of pixels PX may be regions that receive light from an external source of the stack structure ST and convert the same into an electrical signal. For example, the plurality of pixels PX may include a photoelectric conversion region PD that receives light of an external source, and transistors forming a pixel circuit that convert photocharges accumulated in the photoelectric conversion region PD into an electrical signal.

The pad region PDR may be disposed on at least one side of the active pixel region APR, for example, on three sides of the active pixel region APR, as illustrated in FIG. 1. A plurality of external bonding pads 390 may be disposed on the pad region PDR, and configured to transmit or receive an electrical signal with an external device or the like.

The optical black region OB and the connection region CR may be sequentially arranged around the active pixel region APR between the active pixel region APR and the pad region PDR. The optical black region OB may be a region in which light is blocked, and may include optical black pixels PX′ that generate a dark signal to function as a reference pixel for the active pixel region APR, and dummy pixels DX may be further disposed around the optical black pixels PX′ (see FIG. 2). The connection region CR may be disposed at one side of the optical black region OB, but this is merely an illustrative example. The connection region CR may be configured to transmit and/or receive an electrical signal of the photoelectric conversion region PD to and/or from a circuit of a second substrate 210 by connecting a first interconnection 125 and a second interconnection 225 by first connection structures 362.

As described above, referring to FIG. 3, the image sensor 10 according to the present embodiment may include the stack structure ST having the first substrate structure 100 and the second substrate structure 200.

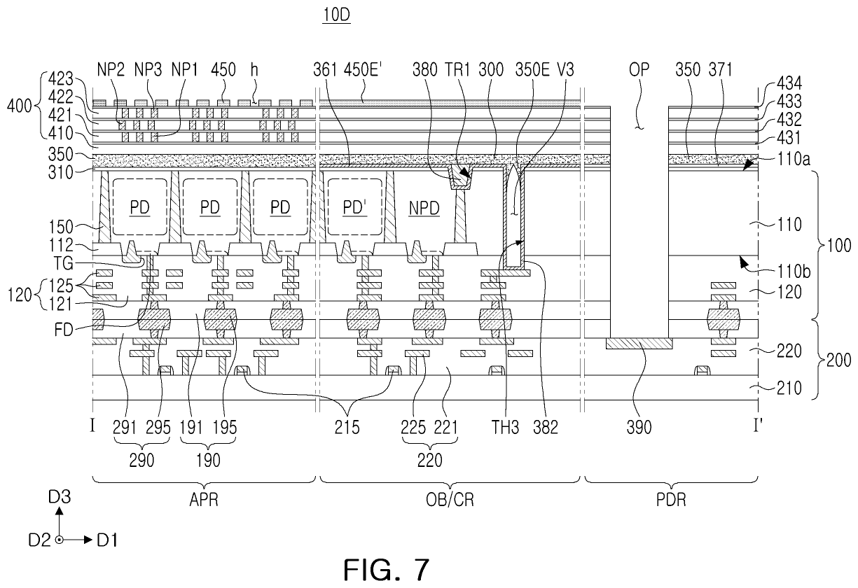

The first substrate structure 100 may include the first substrate 110 having a second surface 110a and a first surface 110b, being opposite to each other, a front optical structure 300 (see FIG. 7) on the second surface 110a of the first substrate 110, and a first interconnection structure 120 on the first surface 110b of the first substrate 110. The second substrate structure 200 may include a second substrate 210 having an upper surface on which logic elements 215 are disposed, and a second interconnection structure 220 on the second substrate 210 and contacting the first interconnection structure 120. The first substrate structure 100 may also be referred to as a ‘sensor chip,’ and the second substrate structure 200 may also be referred to as a ‘logic chip.’ The image sensor according to the present embodiment is illustrated as a stack structure having two substrates, but is not limited thereto, and in some embodiments, may include a stack structure having at least three substrates. For example, at least some of the transistors for the pixel circuit may be implemented on a separate substrate, not the first substrate 110.

The image sensor 10 according to the present embodiment may include a meta-optical structure 400 instead of an optical lens. In this case, the meta-optical structure 400 may refer to an optical structure based on meta-optics, and may be also called a meta-surface or a meta-lens.

In the present embodiment, the meta-optical structure 400 may be disposed on the second surface 110a of the first substrate 110, which may be an incident surface, and may be configured to disperse incident light according to a wavelength (e.g., color) and focus the dispersed light onto photoelectric conversion regions PD of different pixels PX.

Referring to FIG. 3, the meta-optical structure 400 may be a multilayer structure including a plurality of dielectric layers 410, 421, 422, and 423, and may include nano-prism patterns NP1, NP2, and NP3 which may be nano-scale structures (e.g., post structures) disposed in at least one dielectric layer (e.g., at least one of 421, 422, and 423) among the plurality of dielectric layers 410, 421, 422, and 423. In the present embodiment, a inorganic layer 350 including an inorganic material may be disposed on the second surface 110a of the first substrate 110, and the meta-optical structure 400 may be disposed on the inorganic layer 350.

The nano-prism patterns NP1, NP2, and NP3 may be disposed in an overlapping region in the active pixel region APR. The plurality of dielectric layers 410, 421, 422, and 423 may extend to the pad region PDR through the optical black region OB and the connection region CR, as well as the active pixel region APR.

The first substrate 110 of the first substrate structure 100 may be a semiconductor substrate. For example, the first substrate 110 may be a bulk silicon substrate or a silicon-on-insulator (SOI) substrate.

The first substrate 110 may include a isolation pattern 150 defining the plurality of pixels PX. The isolation pattern 150 may surround photoelectric conversion regions PD. At least one photoelectric conversion region PD may be provided in the first substrate 110 for each of the plurality of pixels PX. The photoelectric conversion regions PD may generate charges in proportion to an amount of light incident from the external source. For example, the photoelectric conversion regions PD may be photo diodes, photo transistors, photo gates, pinned photo diodes, or organic photo diodes. The photoelectric conversion regions PD may be disposed in the active pixel region APR.

In addition, as described above, in an optical black region adjacent to the active pixel region APR, a reference photoelectric conversion region PD′ may be included in a reference pixel RX that generates a dark signal for reference to the active pixel region APR. In addition, a dummy photoelectric conversion region NPD may be provided as a dummy pixel region DX not provided as a photoelectric conversion element. The reference photoelectric conversion region PD′ and the dummy photoelectric conversion region NPD may also be separated by the isolation pattern 150.

The isolation pattern 150 may have a lattice shape isolating the plurality of pixels PX in a plan view. For example, the isolation pattern 150 may pass through at least a portion of the first substrate 110. In the present embodiment, the isolation pattern 150 may include a deep trench extending from the first surface 110b to the second surface 110a. The isolation pattern 150 may include an insulating liner (not illustrated) on a sidewall of the deep trench, and a filling portion filled in the insulating liner. For example, the insulating liner may include silicon oxide, silicon nitride, and/or silicon oxynitride, and the filling portion may include a semiconductor material or a conductive material. For example, the filling portion may include impurity-doped polycrystalline silicon.

An element isolation pattern 112 defining an active region may be provided on the first surface 110b of the first substrate 110. A floating diffusion region FD and elements for the pixel circuit may be provided in the active region. Pixel circuit elements may include circuit elements such as various transistors such as a transfer gate TG or the like. The isolation pattern 150 may be connected to the element isolation pattern 112, which may be a shallow trench structure. In the present embodiment, the element isolation pattern 112 may be disposed on the isolation pattern 150. For example, the element isolation pattern 112 may include silicon oxide.

The first interconnection structure 120 may include a first inter-interconnection insulating layer 121 and a plurality of first interconnections 125 in the first inter-interconnection insulating layer 121. A number of layers and an arrangement of interconnections included in the first interconnection structure 120, illustrated in the drawings, are merely illustrative examples. For example, the first inter-interconnection insulating layer 121 may include at least one of silicon oxide, silicon nitride, silicon oxynitride, or a low-κ material having a lower dielectric constant than silicon oxide. For example, the first interconnections 125 may include at least one of tungsten (W), copper (Cu), aluminum (Al), gold (Au), silver (Ag), or an alloy thereof.

The second substrate 210 may be a bulk silicon substrate or an SOI substrate, similar to the first substrate 110. The logic elements 215 may be disposed on the second substrate 210. The logic elements 215 may form a circuit that provides a certain signal to each of the pixels PX of the active pixel region APR and/or controls an output signal from each of the pixels PX. For example, the logic elements 215 may include various transistors forming a control register block, a timing generator, a ramp signal generator, a row driver, a readout circuit, and/or an input/output buffer (I/O) circuit.

The second interconnection structure 220 may be disposed between the first interconnection structure 120 of the first substrate structure 100 and the second substrate 210. The second interconnection structure 220 may include a second inter-interconnection insulating layer 221 and a plurality of second interconnections 225 on the second inter-interconnection insulating layer 221. A number of layers and an arrangement of interconnections constituting the second interconnection structure 220, illustrated in the drawings, are merely illustrative examples. The plurality of second interconnections 225 may include vias electrically connecting the logic elements 215. For example, the second interconnection inter-insulating layer 221 may include at least one of silicon oxide, silicon nitride, silicon oxynitride, or a low-κ material having a lower dielectric constant than silicon oxide. The second interconnections 225 may include at least one of tungsten (W), copper (Cu), aluminum (Al), gold (Au), silver (Ag), or an alloy thereof.

In the present embodiment, the first interconnection structure 120 may be bonded to the second interconnection structure 220. In some embodiments, the first and second interconnection structures 120 and 220 may include a bonding insulating layer (not illustrated) disposed on a surface to be bonded. In addition, the first and second substrate structures 100 and 200 may be electrically connected to each other by a first connection structure 362 and a second connection structure 372 passing through the first substrate structure 100. The first and second connection structures 362 and 372 may be respectively disposed in the pad region PDR and the connection region CR, and may electrically connect the first interconnection 125 and the second interconnection 225.

Referring to FIG. 3, the first substrate structure 100 may include the surface insulating layer 310 and the inorganic layer 350, sequentially disposed on the second surface 110a of the first substrate 110.

The surface insulating layer 310 may be disposed on the second surface 110a of the first substrate 110. A height of the inorganic layer in a first direction perpendicular to the second surface of the substrate on the active pixel region is more than 20 times greater than a height of the insulating layer in the first direction. The surface insulating layer 310 may extend to a peripheral region (OB/CR) and the pad region PDR as well as the active pixel region APR. The surface insulating layer 310 may include an insulating material. For example, the surface insulating layer 310 may include at least one of silicon oxide, silicon nitride, silicon oxynitride, aluminum oxide, hafnium oxide, or any combination thereof, but is not limited thereto. In addition, the surface insulating layer 310 may be a multiple-layered layer. For example, the surface insulating layer 310 may include an aluminum oxide film, a hafnium oxide film, a silicon oxide film, a silicon nitride film, or a hafnium oxide film, which may be sequentially stacked on the second surface 110a of the first substrate 110, but is not limited thereto. The surface insulating layer 310 may function as an anti-reflective film to prevent reflection of light incident on the first substrate 110, thereby improving a light reception rate of the photoelectric conversion region PD.

In the present embodiment, color filters and configurations related thereto (e.g., grid pattern) on the surface insulating layer 310 may be omitted. Since the meta-optical structure 400 may be configured to have excellent wavelength selectivity by region, color filters disposed in each of the pixels PX may be omitted.

In this manner, by omitting the color filter and the configurations related thereto, a manufacturing process may be simplified and may be implemented in a thinner thickness, and temperature constraints due to an organic material constituting a color filter may be resolved. For example, after the color filter is formed, it is difficult to introduce a process of a high temperature (e.g., 200° C. or higher), and there may be a concern that delamination and/or a crack may occur in the color filter due to a difference in coefficients of thermal expansions with other components that are in contact with the color filter. By omitting the color filter, which may be an organic material, these constraints may be fundamentally resolved.

Referring to FIG. 3, in the peripheral region (OB/CR), a first conductive layer 361 and a light-blocking filter layer 340L may be sequentially disposed on the surface insulating layer 310. In some embodiments, the light-blocking filter layer 340L may provide the optical black region OB, and may be provided as a light-blocking structure that blocks light together with the first conductive layer 361. In the present embodiment, the light-blocking filter layer 340L may include an inorganic material, similar to the inorganic layer 350. For example, the light-blocking filter layer 340L may include TiO₂, ZnO, or Al₂O₃. In some embodiments, the light-blocking filter layer 340L may include an organic material.

Referring to FIG. 3, a bias contact plug 380 and the first conductive layer 361 may be disposed in the optical black region OB. The first conductive layer 361 may cover the surface insulating layer 310 on the second surface 110a of the first substrate 110. In addition, the first conductive layer 361 may conformally cover an inner wall of a first shallow trench TR1, and may be connected to the isolation pattern 150. The bias contact plug 380 may fill the first trench TR1. The bias contact plug 380 may include a metal material (e.g., aluminum). The bias contact plug 380 may be connected to the isolation pattern 150 through the first conductive layer 361. A bias may be applied to the isolation pattern 150 through the bias contact plug 380.

The first connection structure 362 may be disposed in the connection region CR. The first connection structure 362 may include a first pattern formed along an inner sidewall of a second trench TR2 extending through the first substrate 110 and the first interconnection structure 120 to the second interconnection structure 220. The first pattern may electrically connect the first interconnection 125 and the second interconnection 225. In this manner, the first connection structure 362 may electrically connect the first substrate structure 100 and the second substrate structure 200 (in particular, the first interconnection 125 and the second interconnection 225 by passing through the first interconnection structure 120 and a portion of the second interconnection structure 220). The first connection structure 362 may be formed together with the first conductive layer 361. For example, the first connection structure 362 may include a metal material (e.g., tungsten).

The second connection structure 372 and the external bonding pad 390 may be disposed in the pad region PDR. The second connection structure 372 may include a second pattern formed along an inner sidewall of a third trench TR3 passing through the first substrate 110 and the first interconnection structure 120 to extend to the second interconnection structure 220. The second pattern may electrically connect the external bonding pad 390 and the second interconnection 225.

Similar to the first connection structure 362, the second connection structure 372 may connect the first substrate structure 100 and the second substrate structure 200 (in particular, the first interconnection 125 and the second interconnection 225 by passing through the first interconnection structure 120 and a portion of the second interconnection structure 220) to each other. A second conductive layer 371 may be disposed on the surface insulating layer 310 on the second surface 110a of the first substrate 110. The second conductive layer 371 may conformally cover an inner wall of a second trench TR2. Similarly, the second pattern extended from the second conductive layer 371 may be conformally formed to extend into the third trench TR3, and may be provided as the second connection structure 372. The second conductive layer 371 and the second connection structure 372 may include the same metal material (for example, tungsten).

In the present embodiment, the external bonding pad 390 may be formed by filling in the second trench TR2. The external bonding pad 390 may include a metal material (for example, aluminum). The external bonding pad 390 may connect the second conductive layer 371 and the second connection structure 372 to the second interconnection 225, and may be connected to the logic elements 215 of the second substrate 210 through the second interconnection 225. The external bonding pad 390 may serve as an electrical connection path between the image sensor 10 and the external element. For example, an electrical signal generated from the photoelectric conversion regions PD in the plurality of pixels PX of the active pixel region APR may be processed by a pixel circuit of the first substrate 110 and a logic circuit of the second substrate 210, and may be transmitted to the external element through the external bonding pad 390.

Referring to FIG. 3, the inorganic layer 350 may be formed not only in the active pixel region APR, but also in the optical black region OB and the connection region CR, which may be surrounding regions, and in the pad region PDR. The inorganic layer 350 may cover the light-blocking filter layer 340L and the first and second connection structures 362 and 372 on the second surface 110a of the first substrate 110, and may provide a flat upper surface.

The inorganic layer 350 may be a transparent planarization layer and may include a light-transmitting inorganic material. In some embodiments, the inorganic layer 350 may include an oxide such as tetraethyl orthosilicate (TEOS). However, the inorganic layer 350 is not limited thereto, and for example, may include a spin-on hardmask (SOH), a flowable oxide (FOX), a Tonen silazen (TOSZ), undoped silica glass (USG), borosilica glass (BSG), phosphosilaca glass (PSG), borophosphosilica glass (BPSG), plasma enhanced tetraethyl orthosilicate (PETEOS), fluoride silicate glass (FSG), a high density plasma (HDP) oxide, a plasma enhanced oxide (PEOX), a flowable chemical vapor deposition (CVD) (FCVD) oxide, or any combination thereof. The inorganic layer 350 may have a flat upper surface by using a chemical vapor deposition, a flowable CVD process, or a spin coating process. During a formation process of the inorganic layer 350, a void V1 in the first connection structure 362 and a void V2 in the second connection structure 372 may be partially filled.

As illustrated in FIG. 3, the first connection structure 362 may include the void V1 surrounded by the first pattern, and the inorganic layer 350 may have a first extension portion 350E1 extending into the void V1 of the first connection structure 362. The first extension portion 350E1 may fill an upper region of the void V1. Similarly, the second connection structure 372 may include the void V2 surrounded by the second pattern, and the inorganic layer 350 may have a second extension portion 350E2 extending into the void V2 of the second connection structure 372. The second extension portion 350E2 may fill an upper region of the void V2.

In the present embodiment, the meta-optical structure 400 may be provided on the inorganic layer 350. As described above, the meta-optical structure 400 may include the dielectric layers 410, 421, 422, and 423 and the nano-prism patterns NP1, NP2, and NP3 disposed in the at least one dielectric layer (e.g., at least one of 421, 422, and 423) among the plurality of dielectric layers 410, 421, 422, and 423.

As such, in the present embodiment, the inorganic layer 350 may include an inorganic material, similar to the meta-optical structure 400, to effectively prevent deformation (e.g., peeling, cracking, or the like) due to a coefficient of thermal expansion with the meta-optical structure 400.

The meta-optical structure 400 employed in the present embodiment may include three nano-prism structure layers on a base dielectric layer 410. Specifically, the three nano-prism structure layers may include a first molded layer 421 having first nano-prism patterns NP1, a second molded layer 422 disposed on the first molded layer 421 and having second nano-prism patterns NP2, and a third molded layer 423 disposed on the second molded layer 422 and having third nano-prism patterns NP3.

The first to third nano-prism patterns NP1, NP2, and NP3 may be appropriately designed in terms of a refractive index, a shape, and/or a height according to a wavelength. To obtain a height for securing a desired phase difference, the nano-prism pattern employed in the present embodiment may be disposed in three molded layers 421, 422, and 423. The first to third nano-prism patterns NP1, NP2, and NP3 may be disposed such that some thereof overlap each other. The meta-optical structure 400 that may be employed in the present embodiment is not limited to this arrangement, and nano-prism patterns may be disposed in various forms (shape, height, overlapping, or the like) on one molded layer or three or more molded layers.

For example, the first to third molded layers 421, 422, and 423 may include a transparent inorganic material such as silicon oxide, silicon oxynitride, silicon nitride, silicon carbonate, or silicon carbonitride. The base dielectric layer 410 may include a material that may be the same as or similar to the first to third molded layers 421, 422, and 423. The first to third nano-prism patterns NP1, NP2, and NP3 may be selected from a material having an appropriate refractive index depending on a wavelength of incident light. For example, the first to third nano-prism patterns NP1, NP2, and NP3 may include a transparent inorganic material such as titanium oxide, silicon nitride, niobium oxide, tantalum oxide, aluminum oxide, or hafnium oxide.

In some embodiments, as illustrated in FIG. 3, in the meta-optical structure 400, first to third etching stop films 431, 432, and 433 may be disposed between the base dielectric layer 410 and the first to third molded layers 421, 422, and 423, respectively. The first etching stop film 431 may be used to form holes for the first nano-prism patterns NP1 in the first molded layer 421. Similarly, the second and third etching stop films 432 and 433 may be used to form holes for the second and third nano-prism patterns NP2 and NP3 in the second and third molded layers 422 and 423, respectively. For example, the first and second etching stop films 431 and 432 may include, for example, aluminum oxide.

The meta-optical structure 400 employed in the present embodiment may include an anti-reflection layer 450 on the third molded layer 423. The anti-reflection layer 450 may prevent reflection of light incident on the meta-optical structure 400 to increase a light reception rate. The anti-reflection layer 450 may include a material having a different refractive index from a material of the third molded layer 423. For example, the anti-reflection layer 450 may include silicon nitride, aluminum oxide, or hafnium oxide. In the present embodiment, the anti-reflection layer 450 may include a plurality of holes h (see FIG. 2). The holes h may be provided in the anti-reflection layer 450, not only to prevent light interference, but also to increase light absorbance to improve an anti-reflection function. In some embodiments, a fourth etching stop film 434 may be disposed between the anti-reflection layer 450 and the third molded layer 423 to form the plurality of holes h.

As described above, the first to third nano-prism patterns NP1, NP2, and NP3 may be disposed only in the active pixel region APR, but the base dielectric layer 410 and the first to third molded layers 421, 422, and 433 may extend to the peripheral region (OB/CR) and the pad region PDR.

A pad opening OP that exposes the external bonding pad 390 may be formed by extending through the meta-optical structure 400, the inorganic layer 350, and the surface layer 310 in the pad region PDR. The external bonding pad 390 may be exposed by the pad opening OP in the pad region PDR, to be connected to an external device.

In the present embodiment, a plurality of interfaces on a plurality of layers may be exposed on an inner sidewall of the pad opening OP. Although not limited thereto, the inorganic layer 350 may have a side surface 350S that may be relatively concave than each of the layers (e.g., 410, 421, 422, and 433) of the meta-optical structure 400. A concave depth, as above, may be understood as a difference in compactness of a film material due to a difference in a formation process rather than a difference in a component material. For example, since the meta-optical structure 400 may be formed by chemical vapor deposition, physical vapor deposition, sputtering, or atomic layer deposition, the meta-optical structure 400 may have a film material that may be relatively compact than the inorganic layer 350.

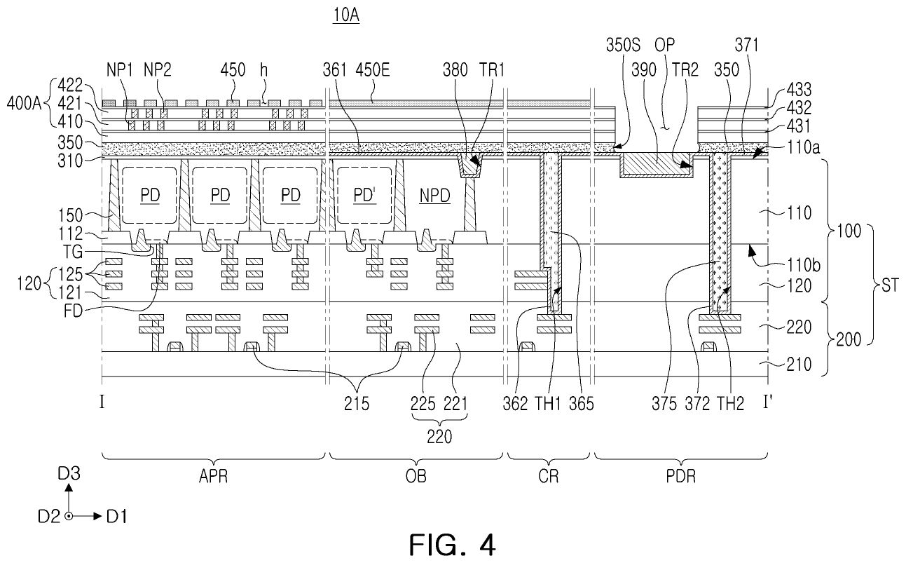

FIG. 4 is a cross-sectional side view illustrating an image sensor according to an embodiment.

Referring to FIG. 4, an image sensor 10A according to the present embodiment may have a structure similar to that of the image sensor 10 illustrated in FIGS. 1 to 3 (particularly, FIG. 3), except that a meta-optical structure 400A includes two nano-prism structure layers. Specifically, a first organic material filling portion 365 and a second organic material filling portion 375 may be disposed in voids of first and second connection structures 362 and 372, respectively, and a light-blocking filter layer may be omitted in an optical black region OB. In addition, components of the present embodiment may be understood by referring to description of the same or similar components of the image sensor 10 illustrated in FIGS. 1 to 3, unless otherwise specifically described.

The meta-optical structure 400A employed in the present embodiment may include a nano-prism structure layer different from the previous embodiment of FIGS. 1 to 3. The meta-optical structure 400A may include a first molded layer 421 having first nano-prism patterns NP1 on a base dielectric layer 410, and a second molded layer 422 having second nano-prism patterns NP2 on the first molded layer 421. The nano-prism patterns NP1 and NP2 may be disposed in an overlapping region in an active pixel region APR. To obtain a height for securing a desired phase difference, the first and second nano-prism patterns NP1 and NP2 may be disposed in the two molded layers 421 and 422, respectively. In the present embodiment, the first and second nano-prism patterns NP1 and NP2 may be disposed to partially overlap each other.

The first and second organic material filling portions 365 and 375 may be disposed in the voids of the first and second connection structures 362 and 372, respectively. As illustrated in FIG. 4, the first organic material filling portion 365 filled with an organic material may be provided in a void surrounded by the first connection structure 362. Similarly, the second organic material filling portion 375 filled with an organic material may be provided in a void surrounded by the second connection structure 372.

In the present embodiment, unlike the previous embodiment(s), the light-blocking filter layer may be omitted in the optical black region OB. In general, the light-blocking filter layer may be provided together with a color filter of the active pixel region APR, but may not be provided together with the color filter. In the present embodiment, an anti-reflection layer 450 may have an extension portion 450E in a peripheral region (e.g., optical black region OB and connection region CR). The extension portion 450E may not include a hole and substantially cover the peripheral region entirely, and may partially perform a role of the light-blocking filter layer.

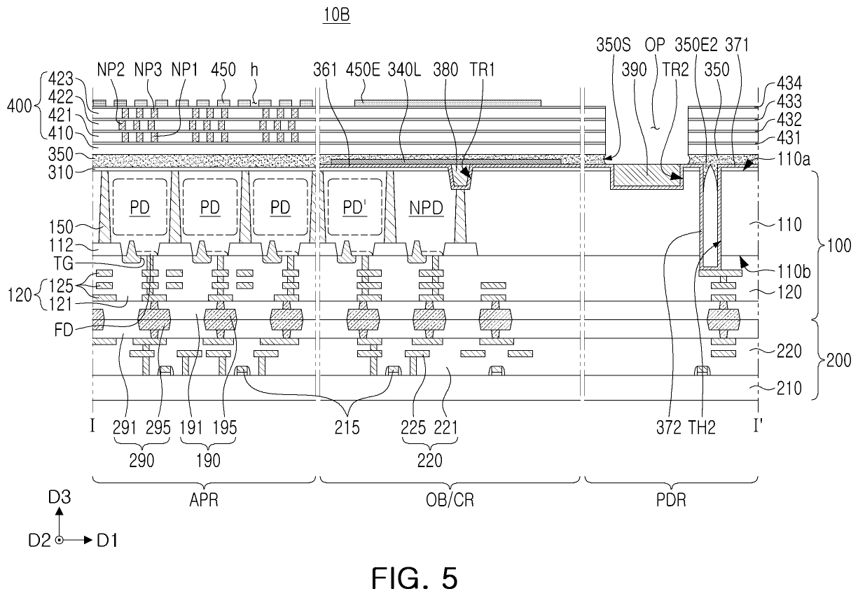

FIG. 5 is a cross-sectional side view illustrating an image sensor according to an embodiment.

Referring to FIG. 5, an image sensor 10B according to the present embodiment has a structure similar to the image sensor 10 illustrated in FIGS. 1 to 3 (particularly, FIG. 3), except that a first substrate structure 100 and a second substrate structure 200 are connected by metal-dielectric hybrid bonding. Components of the present embodiment may be understood by referring to description of the same or similar components of the image sensor 10 illustrated in FIGS. 1 to 3, unless otherwise specifically described.

Unlike the previous embodiment(s), the image sensor 10B according to the present embodiment may connect the first substrate structure 100 and the second substrate structure 200 in a different manner, not using a first connection structure and/or a second connection structure. Specifically, the first substrate structure 100 and the second substrate structure 200 may be connected by metal-dielectric hybrid bonding.

As illustrated in FIG. 5, a first bonding structure 190 and a second bonding structure 290 may be respectively disposed on surfaces of a first interconnection structure 120 and a second interconnection structure 220 that face each other, and the first and second bonding structures 190 and 290 may be electrically and mechanically coupled.

The first bonding structure 190 may include a first bonding insulating layer 191 disposed on the first interconnection structure 120, and first bonding pads 195 electrically connected to a first interconnection 125 on a bonding surface of the first bonding insulating layer 191. The first bonding pads 195 may have a surface, substantially coplanar with the bonding surface of the first bonding insulating layer 191.

Similarly, the second bonding structure 290 may include a second bonding insulating layer 291 disposed on the second interconnection structure 220, and second bonding pads 295 electrically connected to the second interconnection 225 on a bonding surface of the second bonding insulating layer 291. The second bonding pads 295 may have a surface, substantially coplanar with the bonding surface of the second bonding insulating layer 291.

The first and second bonding structures 190 and 290 may be hybrid bonded through a high-temperature annealing process while in a state bonded to each other. The hybrid bonding may include intermetallic bonding of the first and second bonding pads 195 and 295, and inter-dielectric bonding of the first and second bonding insulating layers 191 and 291. By this hybrid bonding, the first substrate structure 100 and the second substrate structure 200 may be firmly bonded not only to each other, but also the first and second interconnections 125 and 225 may be electrically connected through the intermetallic bonding. Therefore, the first and second bonding pads 195 and 295 may replace the first and second connection structures 362 and 372 used to connect the first and second interconnections 125 and 225 in the previous embodiments (see FIGS. 3 and 4).

An external bonding pad 390 may be disposed on a first substrate 110, in a similar manner to the previous embodiments (see FIGS. 3 and 4), and may be exposed by a pad opening OP passing through a meta-optical structure 400 and a inorganic layer 350. Referring to FIG. 5, a stack structure may include a trench TH2 extending through the first substrate 110 at one side of the external bonding pad 390 to the first interconnection structure 120. A pad connection structure 372 may extend into the trench TH2, and may include a pattern electrically connecting the external bonding pad 390 and the first interconnection 125. The inorganic layer 350 may include an extension portion 350E2 filling a void V2 surrounded by the pad connection structure 372. The second extension portion 350E2 may fill an upper region of the void V2.

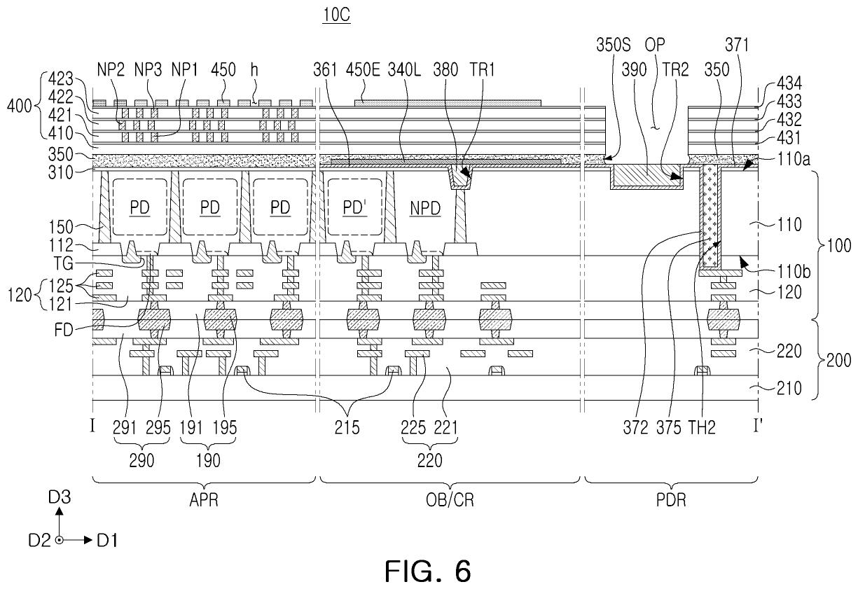

FIG. 6 is a cross-sectional side view illustrating an image sensor according to an embodiment.

Referring to FIG. 6, an image sensor 10C according to the present embodiment has a structure similar to the image sensor 10 illustrated in FIGS. 1 to 3 (particularly, FIG. 3), except that a first substrate structure 100 and a second substrate structure 200 are connected by metal-dielectric hybrid bonding, and an organic material filling portion 375 is disposed in a pad connection structure 372. Components of the present embodiment may be understood by referring to description of the same or similar components of the image sensor 10 illustrated in FIGS. 1 to 3, unless otherwise specifically described.

In the present embodiment, the first substrate structure 100 and the second substrate structure 200 may be connected by metal-dielectric hybrid bonding, similar to the embodiment described in FIG. 5.

A first bonding structure 190 and a second bonding structure 290 may be respectively disposed on surfaces of a first interconnection structure 120 and a second interconnection structure 220 that face each other, and the first and second bonding structures 190 and 290 may be electrically and mechanically coupled.

The first bonding structure 190 may include a first bonding insulating layer 191 disposed on the first interconnection structure 120, and first bonding pads 195 electrically connected to the first interconnection 125 on a bonding surface of the first bonding insulating layer 191, and similarly, the second bonding structure 290 may include a second bonding insulating layer 291 disposed on the second interconnection structure 220, and second bonding pads 295 electrically connected to the second interconnection 225 on a bonding surface of the second bonding insulating layer 291.

The first substrate structure 100 and the second substrate structure 200 may not be only firmly bonded to each other by intermetallic bonding of the first and second bonding pads 195 and 295, and inter-dielectric bonding of the first and second bonding insulating layers 191 and 291, but also the first and second interconnections 125 and 225 may be electrically connected through the intermetallic bonding.

Similar to the previous embodiment (see FIG. 5), an external bonding pad 390 may be disposed on a first substrate 110, and may be exposed by a pad opening OP passing through a meta-optical structure 400 and a inorganic layer 350. The image sensor 10C according to the present embodiment may include the organic material filling portion 375 filling a void V2 surrounded by the pad connection structure 372.

FIG. 7 is a cross-sectional side view illustrating an image sensor according to an embodiment.

Referring to FIG. 7, an image sensor 10D according to the present embodiment has a structure similar to the image sensor 10C illustrated in FIG. 6, except that an external bonding pad 390 is disposed on a second substrate 210, a pad opening OP passes through a first substrate structure 100, and a ground connection structure 382 is further employed in a connection region CR. Components of the present embodiment may be understood by referring to description of the same or similar components of the image sensor 10 illustrated in FIGS. 1 to 3 and the image sensor 10C illustrated in FIG. 6, unless otherwise specifically described.

In the present embodiment, the external bonding pad 390 may be disposed on a second substrate structure 200, particularly the second substrate 210. The pad opening OP may pass through the first substrate structure 100, and the external bonding pad 390 may be exposed by the pad opening OP. The first substrate structure 100 and the second substrate structure 200 may be electrically and mechanically connected by first and second bonding structures 190 and 290.

The image sensor 10D according to the present embodiment may include a fourth trench TR4 extending through a first substrate 110 to a first interconnection structure 120 in the connection region CR. The ground connection structure 382 may include a pattern extending into the fourth trench TR4 and connected to a first interconnection 125. A inorganic layer 350 may include an extension portion 350E partially filling a void V3 surrounded by the ground connection structure 382.

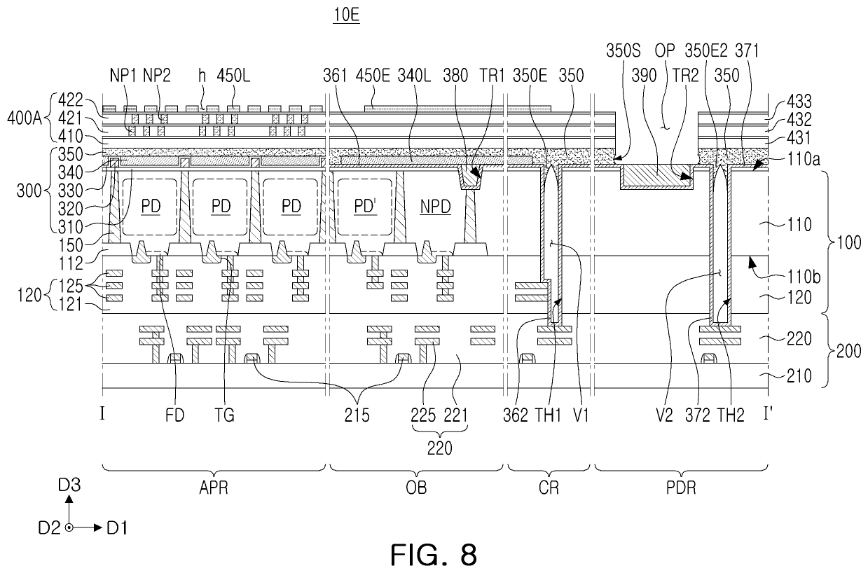

FIG. 8 is a cross-sectional side view illustrating an image sensor according to an embodiment.

Referring to FIG. 8, an image sensor 10E according to the present embodiment has a structure similar to the image sensor 10 illustrated in FIGS. 1 to 3 (particularly, FIG. 3), except that a meta-optical structure 400A includes two nano-prism structure layers and color filters 340 and configurations related thereto are further included. Components of the present embodiment may be understood by referring to description of the same or similar components of the image sensor 10 illustrated in FIGS. 1 to 3, unless otherwise specifically described.

The meta-optical structure 400A employed in the present embodiment may include a nano-prism structure layer different from the previous embodiment (see FIGS. 1 to 3). The meta-optical structure 400A may include a first molded layer 421 having first nano-prism patterns NP1 on a base dielectric layer 410, and a second molded layer 422 having second nano-prism patterns NP2 on the first molded layer 421. The nano-prism patterns NP1 and NP2 may be disposed in an overlapping region in an active pixel region APR. The first and second nano-prism patterns NP1 and NP2 employed in the present embodiment may be disposed to partially overlap the first and second nano-prism patterns NP1 and NP2 each other.

In the present embodiment, a first substrate structure 100 may include a front optical structure 300 disposed on a second surface 110a of the first substrate 110. The front optical structure 300 may include a surface insulating layer 310, a grid pattern 320, a protective film 330, color filters 340, and a inorganic layer 350, together with the meta-optical structure 400A described above.

The surface insulating layer 310 may be disposed on the second surface 110a of the first substrate 110. The surface insulating layer 310 may extend to a peripheral region (OB/CR) and a pad region PDR as well as the active pixel region APR. The surface insulating layer 310 may include an insulating material. For example, the surface insulating layer 310 may include at least one of silicon oxide, silicon nitride, silicon oxynitride, aluminum oxide, hafnium oxide, or any combination thereof, but is not limited thereto. In addition, the surface insulating layer 310 may be a multiple-layered layer. For example, the surface insulating layer 310 may include an aluminum oxide film, a hafnium oxide film, a silicon oxide film, a silicon nitride film, and a hafnium oxide film, which may be sequentially stacked on the second surface 110a of the first substrate 110, but is not limited thereto. The surface insulating layer 310 may function as an anti-reflective film to prevent reflection of light incident on the first substrate 110, thereby improving a light reception rate of the photoelectric conversion region PD.

In the active pixel region APR, the color filters 340 and the grid pattern 320 between the color filters 340 may be disposed on the surface insulating layer 310. The color filters 340 may be disposed on the surface insulating layer 310. The color filters 340 may be disposed to correspond to each pixel PX of the active pixel region APR. The color filters 340 may have various color filters depending on each pixel. For example, the color filters 340 may include a red color filter, a green color filter, and a blue color filter. In some embodiments, the color filters 340 may be disposed in a Bayer pattern. However, this is only illustrative and limiting. For example, the color filters 340 may include a yellow filter, a magenta filter, and a cyan filter, and may further include a white filter.

The grid pattern 320 may have a grid shape in a plan view. In some embodiments, the grid pattern 320 may be disposed to overlap a isolation pattern 150 in a vertical direction (e.g., D3). In some embodiments, the grid pattern 320 may include a conductive pattern and a low refractive index pattern. The conductive pattern may effectively prevent electrostatic discharge (ESD) failure by preventing charges generated by ESD or the like from accumulating on a surface of the first substrate 110. The low refractive index pattern may improve a light collection efficiency by refracting or reflecting light incident obliquely, thereby improving quality of an image sensor. For example, the conductive pattern may include at least one of titanium (Ti), titanium nitride (TiN), tantalum (Ta), tantalum nitride (TaN), tungsten (W), aluminum (Al), or copper (Cu). In addition, the low refractive index pattern may include a low refractive index material having a lower refractive index than silicon (Si). For example, the low refractive index pattern may include at least one of silicon oxide, aluminum oxide, tantalum oxide, or any combination thereof.

Referring to FIG. 8, in the peripheral region (OB/CR), a first conductive layer 361 and a light-blocking filter layer 340L may be sequentially disposed on the surface insulating layer 310. The light-blocking filter layer 340L may be provided in the optical black region OB, and may be provided as a light-blocking structure that blocks light together with the first conductive layer 361. In the present embodiment, the light-blocking filter layer 340L may be provided together with a portion of the color filters 340. The light-blocking filter layer 340L may have a thickness substantially the same as that of the color filters 340, but is not limited thereto. The light-blocking filter layer 340L may include a blue color filter or a black filter.

In the present embodiment, in a similar manner to the previous embodiments, the inorganic layer 350 may be provided in the active pixel region APR, as well as a surrounding region thereof, such as the optical black region OB and the connection region CR, and the pad region PDR. The inorganic layer 350 may cover the color filters 340, the light-blocking filter layer 340L, and first and second connection structures 362 and 372 on the second surface 110a of the first substrate 110, and may provide a flat upper surface. The inorganic layer 350 may include a light-transmitting inorganic material. For example, the inorganic layer 350 may include an oxide such as TEOS. In the present embodiment, the inorganic layer 350 may include an inorganic material, similar to the meta-optical structure 400A, to effectively prevent deformation (e.g., peeling, cracking, or the like) due to a coefficient of thermal expansion with the meta-optical structure 400A.

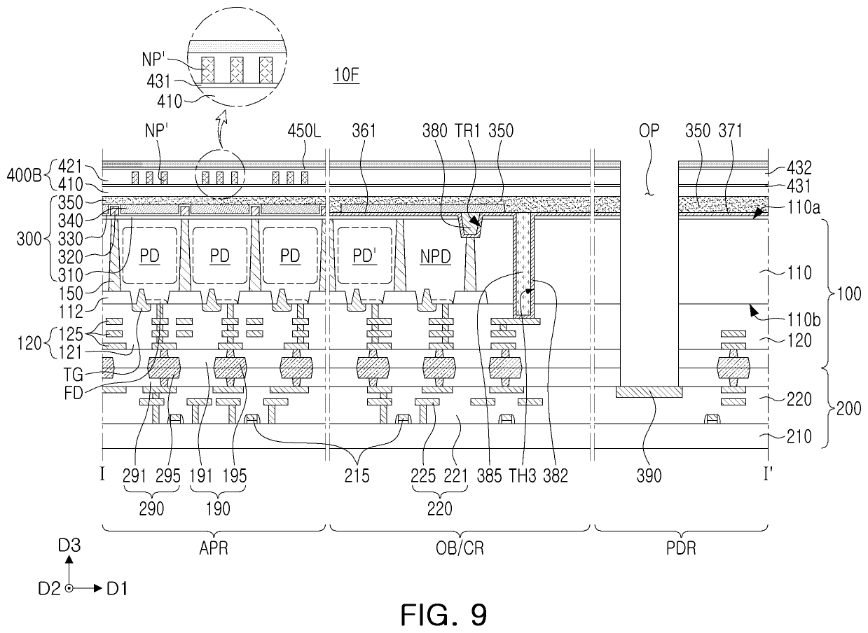

FIG. 9 is a cross-sectional side view illustrating an image sensor according to an embodiment.

Referring to FIG. 9, an image sensor 10F according to the present embodiment has a structure similar to the image sensor 10E illustrated in FIG. 8, except that a meta-optical structure 400B includes a single-layer nano-prism structure layer, a first substrate structure 100 and a second substrate structure 200 are connected by metal-dielectric hybrid bonding, an external bonding pad 390 is disposed on a second substrate 210, a pad opening OP passes through the first substrate structure 100, and an organic material filling portion 385 is disposed in a ground connection structure 382. Components of the present embodiment may be understood by referring to description of the same or similar components of the image sensor 10 illustrated in FIGS. 1 to 3 and the image sensor 10E illustrated in FIG. 8, unless otherwise specifically described.

The meta-optical structure 400B employed in the present embodiment may include a single-layer nano-prism structure layer, unlike the previous embodiments. Specifically, the meta-optical structure 400B may include a base dielectric layer 410, nano-prism patterns NP′ on the base dielectric layer 410, and a molded layer 421 covering the nano-prism patterns NP′ on the base dielectric layer 410. In addition, in the present embodiment, an anti-reflection layer 450L may be formed up to an active pixel region APR, a peripheral region (OB/CR), and the pad region PDR without a hole.

In the present embodiment, the first substrate structure 100 and the second substrate structure 200 may be connected by metal-dielectric hybrid bonding, similar to the embodiment described in FIG. 5.

Specifically, as illustrated in FIG. 9, a first bonding structure 190 and a second bonding structure 290 may be respectively disposed on surfaces of a first interconnection structure 120 and a second interconnection structure 220 that face each other, and first and second bonding structures 190 and 290 may be electrically and mechanically coupled. The first bonding structure 190 may include a first bonding insulating layer 191 disposed on the first interconnection structure 120, and first bonding pads 195 electrically connected to a first interconnection 125 on a bonding surface of the first bonding insulating layer 191, and similarly, the second bonding structure 290 may include a second bonding insulating layer 291 disposed on the second interconnection structure 220, and second bonding pads 295 electrically connected to a second interconnection 225 on a bonding surface of the second bonding insulating layer 291.

The first substrate structure 100 and the second substrate structure 200 may be firmly bonded not only to each other by intermetallic bonding of the first and second bonding pads 195 and 295 and inter-dielectric bonding of the first and second bonding insulating layers 191 and 291, but also the first and second interconnections 125 and 225 may be electrically connected through the intermetallic bonding.

In the present embodiment, the external bonding pad 390 may be disposed on the second substrate structure 200, particularly, the second substrate 210. A pad opening OP may pass through the first substrate structure 100, and the external bonding pad 390 may be exposed by the pad opening OP.

The image sensor 10F according to the present embodiment may include a fourth trench TR4 extending from the connection region CR through the first substrate 110 to the first interconnection structure 120. The ground connection structure 382 may extend into the fourth trench TR4, and may include a pattern connected to the first interconnection 125. The organic material filling portion 385 filled with an organic material may be formed in a void V3 surrounded by the ground connection structure 382.

In the present embodiment, a inorganic layer 350 may include a light-transmitting inorganic material similar to the previous embodiments. The inorganic layer 350 may cover the ground connection structure 382 in the connection region CR, and may be in contact with the organic material filling portion 385. In the present embodiment as well, the inorganic layer 350 may include an inorganic material similar to the meta-optical structure 400B, to effectively prevent deformation (e.g., peeling, cracking, or the like) due to a coefficient of thermal expansion with the meta-optical structure 400B.

According to embodiments, a inorganic layer below a meta-optical structure may include an inorganic material, similar to the meta-optical structure, to prevent deformation (e.g., peeling, cracking, or the like) due to a coefficient of thermal expansion, and as a result, reliability of an image sensor may be improved.

Various advantages and effects of the present disclosure are not limited to the above-described contents, and will be easily understood from descriptions of example embodiments.

While example embodiments have been illustrated and described above, it will be apparent to those skilled in the art that modifications and variations could be made without departing from the scope of the present disclosure as defined by the appended claims.

What is claimed is:

1. An image sensor comprising:
a substrate comprising an active pixel region, an optical black region, a pad region, a first surface, and a second surface opposing the first surface;
a plurality of photoelectric conversion regions in the active pixel region;
a first insulating layer on the second surface of the substrate and on the active pixel region;
an inorganic layer on the first insulating layer; and
a meta-optical structure disposed on the inorganic layer, and comprising a first dielectric layer, first nano-prism patterns arranged in the first dielectric layer, a second dielectric layer, and second nano-prism patterns arranged in the second dielectric layer,
wherein the meta-optical structure is disposed on the active pixel region, and
wherein a height of the inorganic layer in a first direction perpendicular to the second surface of the substrate on the active pixel region is more than 20 times greater than a height of the first insulating layer.

2. The image sensor of claim 1, wherein the pad region comprises:
a pad trench at least partially penetrating the substrate from the second surface, and
wherein a portion of the pad trench is filled with the inorganic layer.

3. The image sensor of claim 1, wherein the inorganic layer is disposed on the active pixel region and the optical black region.

4. The image sensor of claim 2, wherein the inorganic layer is disposed on the active pixel region, the optical black region, and the pad region.

5. The image sensor of claim 3, wherein a thickness of the inorganic layer in the first direction on the active pixel region is different from a thickness of the inorganic layer in the first direction on the optical black region.

6. The image sensor of claim 5, wherein the thickness of the inorganic layer in the first direction on the active pixel region is more than 10% greater than the thickness of the inorganic layer in the first direction on the optical black region.

7. The image sensor of claim 6, wherein the optical black region further comprises:
a light-blocking filter layer disposed in the inorganic layer.

8. The image sensor of claim 4, further comprising:
a second insulating layer between the first insulating layer and the inorganic layer; and
a third dielectric layer between the first dielectric layer and the inorganic layer.

9. The image sensor of claim 4, wherein the substrate further comprises a connection region,
wherein the connection region comprises a connection trench, and
wherein a portion of the connection trench is filled with the inorganic layer.

10. The image sensor of claim 4, wherein the height of the inorganic layer in the first direction on the active pixel region is different from a height of the first dielectric layer in the first direction on the active pixel region.

11. The image sensor of claim 10, wherein the height of the inorganic layer in the first direction on the active pixel region is more than 10 times greater than a height of the first dielectric layer in the first direction on the active pixel region.

12. An image sensor comprising:
a substrate comprising an active pixel region, an optical black region, a pad region, a first surface, and a second surface opposing the first surface;
a plurality of photoelectric conversion regions in the active pixel region;
a first insulating layer on the second surface of the substrate and on the active pixel region;
an inorganic layer on the first insulating layer;
a light-blocking filter layer in the inorganic layer; and
a meta-optical structure disposed on the inorganic layer, and comprising a first layer, first nano-prism patterns arranged in the first layer, a second layer, and second nano-prism patterns arranged in the second layer,
wherein the meta-optical structure is disposed on the active pixel region and the optical black region.

13. The image sensor of claim 12, wherein the inorganic layer comprises a bottom surface and a top surface opposing the bottom surface,
wherein a distance from the top surface of the inorganic layer to the meta-optical structure is less than a distance from the bottom surface of the inorganic layer to the meta-optical structure, and
wherein any point of the bottom surface of the inorganic layer on the active pixel region is disposed above the second surface of the substrate.

14. The image sensor of claim 13, further comprising:
a first dielectric layer between the inorganic layer and the first layer on the active pixel region.

15. The image sensor of claim 14, wherein a height of the inorganic layer in a first direction perpendicular to the second surface of the substrate on the active pixel region is greater than a height of the first layer in the first direction on the active pixel region.

16. The image sensor of claim 14, wherein the pad region comprises:
a pad trench at least partially penetrating the substrate from the second surface, and wherein a portion of the pad trench is filled with the inorganic layer.

17. The image sensor of claim 16, wherein the inorganic layer is disposed on the active pixel region, the optical black region, and the pad region.

18. The image sensor of claim 15, wherein the height of the inorganic layer in the first direction on the active pixel region is more than 1.5 times greater than the height of the first layer in the first direction on the active pixel region.

19. An image sensor comprising:
a substrate comprising an active pixel region, an optical black region, a pad region, a first surface, and a second surface opposing the first surface;
a plurality of photoelectric conversion regions in the active pixel region;
a first insulating layer on the second surface of the substrate and on the active pixel region;
an inorganic layer on the first insulating layer; and
a meta-optical structure disposed on the inorganic layer, and comprising a first layer, first nano-prism patterns arranged in the first layer, a second layer, and second nano-prism patterns arranged in the second layer,
wherein the meta-optical structure is disposed on the active pixel region, and
wherein a height of the inorganic layer in a first direction perpendicular to the second surface of the substrate on the active pixel region is greater than a height of the first nano-prism patterns in the first direction on the active pixel region.

20. The image sensor of claim 19, wherein the pad region comprises:
a pad trench at least partially penetrating the substrate from the second surface, wherein a portion of the pad trench is filled with the inorganic layer.
